(19) United States
(12) Patent Application Publication
(10) Pub. No.: US 2015/0378209 A1
(43) Pub. Date: Dec. 31, 2015

(54) SUBSTRATE FOR ELECTRO-OPTICAL DEVICE, ELECTRO-OPTICAL DEVICE, ELECTRONIC EQUIPMENT, AND METHOD FOR MANUFACTURING SUBSTRATE FOR ELECTRO-OPTICAL DEVICE

(71) Applicant: Seiko Epson Corporation, Tokyo (JP)

(72) Inventors: Daisuke Miyawaki, Chitose-shi (JP); Satoshi Ito, Eniwa-shi (JP)

(21) Appl. No.: 14/766,796

(22) PCT Filed: Mar. 3, 2014
(86) PCT No.: PCT/JP2014/001119

§ 371 Date: Aug. 10, 2015

(30) Foreign Application Priority Data
Mar. 5, 2013 (JP) 2013-042665

(51) Int. Cl. G02F 1/1335; C23C 16/50; H01L 27/12

(52) U.S. Cl. CPC G02F 1/133526; H01L 27/1218; C23C 16/50

(57) ABSTRACT

A substrate for an electro-optical device includes a substrate main body 6 having first slopes 72a and 72b and second slopes 73a and 73b that are arranged so as to extend from a back surface 6b of the substrate main body 6 towards a front surface 6a thereof; a first insulating film 81 covering the first slopes and the second slopes; a second groove 75 having third slopes, and fourth slopes and widening in a direction from the rear surface 6b towards the front surface 6a; and a second insulating film 82 covering the second groove 75 and the first insulating film 81, the second slopes rather than the first slopes are arranged on the front surface 6a side, and each of angles between the second slopes and a normal line is greater than each of angles between the first slopes and the normal line.

### TECHNICAL FIELD

The present invention relates to a substrate for an electro-optical device, an electro-optical device using the substrate for an electro-optical device, electronic equipment using the electro-optical device, and a method for manufacturing a substrate for an electro-optical device.

### BACKGROUND ART

As electro-optical devices, for example, active drive type liquid crystal devices used for a light modulation element (light valve) of a liquid crystal projector are known. The liquid crystal device includes an element substrate having a pixel electrode, a counter substrate having a counter electrode, and a liquid crystal layer interposed between the element substrate and the counter substrate, in which a brighter display is desired.

A liquid crystal device is proposed in which for example, a prism element being a light reflection unit is provided in a counter substrate, and incident light which does not contribute to the display is reflected on the prism element and used as a part of display light, such that a brighter display is achieved (PTL 1). The prism element disclosed in PTL 1 has a groove having a cross-section of a substantially isosceles triangular shape which is long in an optical axis direction, and the long sides (the slopes of the groove) of the isosceles triangular shape are light reflection surfaces that reflect incident light. The utilization efficiency of light is enhanced and a brighter display is realized, by forming the prism element having a cross-section of a substantially isosceles triangular shape, in which each of the angles that the long sides being the light reflection surfaces make with the optical axis is preferably as small as possible, for example, each of the angles that the long sides make with the optical axis is 3 degrees or less, and in other words, an apex angle is 6 degrees or less. In such a prism element, a groove having slopes making an angle of 3 degrees or less with the optical axis is formed in the counter substrate by a dry etching method, and an air layer having a lower refractive index than that of the counter substrate is provided in the inside of the groove, such that a prism element is formed in which the slopes are light reflection surfaces.

### CITATION LIST

### Patent Literature

PTL 1: Japanese Unexamined Patent Application Publication No. 2006-215427

### SUMMARY OF INVENTION

### Technical Problem

However, there is a problem in that it is difficult to form a groove having slopes making an angle of 3 degrees or less with the optical axis, in other words, a groove of a steep tapered shape, by using a dry etching method.

Specifically, when forming a groove of a steep tapered shape in a substrate by a dry etching method, there is a need to etch the substrate in a depth direction while accumulating a protective film (such as CF-based polymer) that suppresses the reaction in a lateral direction (a direction orthogonal to a depth direction), on the sidewalls of the groove, by using for example, reactive gas such as fluorine-based gas (CF-based gas). If the impact of such a protective film is excessively strong, etching in the depth direction as well as the lateral direction is suppressed, and it becomes difficult to form a groove of a steep tapered shape (deeply etched groove). In addition, when the etching is performed in the depth direction, a reaction product generated by the reaction between the substrate and the reactive gas is less likely to be discharged from the groove, and an etching rate decreases. Furthermore, in order to continue the etching in the depth direction, a region that causes the etching reaction is required, and a laterally spreading region causing the etching reaction is formed in the bottom of the groove. Since the laterally spreading region is a reflective surface that reflects light in a direction which does not contribute to the display, it is preferable that the bottom of the groove is processed into a pointed shape like a substantially isosceles triangular shape described above. However, it is difficult to process the bottom of the groove into the pointed shape. For example, if the region causing the etching reaction is made to be small, the region becomes the bottom of the pointed shape, but there is a problem that it is difficult to perform etching more deeply.

Thus, there is a problem that it is difficult to form a suitable groove in the prism element described in PTL 1 by the dry etching method.

### Solution to Problem

The present invention has been made to solve at least a part of the problems described above, and it is possible to realize the present invention as the following aspects or application examples.

### APPLICATION EXAMPLE 1

According to the application example, there is provided a substrate for an electro-optical device, including: a substrate that includes a first surface, a second surface facing the first surface, and first slopes and second slopes being arranged from the first surface towards the second surface, and transmits light, a first insulating film that covers the first slopes and the second slopes; a groove that includes third slopes being surfaces of the first insulating film covering the first slopes, and fourth slopes being surfaces of the first insulating film covering the second slopes, and widens in a direction from the second surface towards the first surface; and a second insulating film that covers the groove and the first insulating film, wherein a part of the second insulating film that covers the groove has a set distance with the third slopes. The second slopes rather than the first slopes are arranged on the first surface side. Each of angles that the second slopes make with a normal line of the first surface is greater than each of angles that the first slopes make with the normal line.

According to this application example, first slopes and second slopes are formed so as to be arranged from the first surface towards the second surface, in the first surface of the substrate which transmits light, and thus a previous-stage groove is formed. A groove widening in a direction from the second surface side towards the first surface side is formed, by covering the previous-stage groove with the first insulating film. Further, the groove has third slopes being surfaces of the first insulating film covering the first slopes, and fourth slopes being surfaces of the first insulating film covering the second slopes. Further, a region surrounded (sealed) by the groove and the second insulating film is formed by covering the groove with a second insulating film having a portion arranged away from the third slopes.

The second slopes of the previous-stage groove described above rather than the first slopes are arranged on the first surface side, and each of the angles that the second slopes make with a normal line of the first surface is greater than each of the angles that the first slopes make with the normal line of the first surface. That is, a widened region (opening region) is present in the first surface (front surface) of the substrate for an electro-optical device, and a material for forming the first insulating film is easily entered into the groove. In other words, the substrate for an electro-optical device has a shape for which the entire region (the first slopes and the second slopes) of the previous-stage groove are easily covered with the first insulating film. As a result, it is possible to easily form the groove by covering the previous-stage groove with the first insulating film. In addition, it is possible to form the light reflection surface in an interface between the region surrounded by the groove and the second insulating film and the first insulating film, by covering the groove with the second insulating film, and setting the refractive index of the region surrounded (sealed) by the groove and the second insulating film, and the first insulating film, and the refractive index of the first insulating film to be different from each other. Accordingly, it is possible to easily form a substrate for an electro-optical device having the region surrounded by the groove and the second insulating film as a light reflecting portion.

### APPLICATION EXAMPLE 2

In the substrate for an electro-optical device according to the application example described above, it is preferable that each of angles that the first slopes make with the normal line be in the range of 1 degree to 3 degrees, and each of angles that the second slopes make with the normal line be in the range of 4 degrees to 7 degrees.

When utilizing the groove as the light reflecting portion, it is necessary to control the slopes of the groove being the light reflection surface and the normal line of the first surface so as to have a proper angle. Further, since the groove being the light reflecting portion is formed by covering the previous-stage groove described above with the first insulating film, it is necessary to perform control such that the shape of the previous-stage groove is a shape in which a material for forming the first insulating film is easily entered into the inside. In other words, if each of the angles that the first slopes of the previous-stage groove make with the normal line of the first surface is in the range of 1 degree to 3 degrees, and each of the angles that the second slopes make with the normal line is in the range of 4 degrees to 7 degrees, it is possible to easily cover the previous-stage groove with the first insulating film, and form a groove having proper slopes as the light reflection portion.

### APPLICATION EXAMPLE 3

In the substrate for an electro-optical device according to the application example described above, it is preferable that each of angles that the third slopes make with the normal line be smaller than 3 degrees.

When utilizing the groove as the light reflecting portion, it is necessary to perform control such that the slopes (third slopes) of the groove being the light reflection surface make a proper angle with the normal line of the first surface. In other words, if each of the angles that the third slopes of the groove make with the normal line of the first surface is set to be smaller than 3 degrees, it is possible to improve the performance as the light reflecting portion.

### APPLICATION EXAMPLE 4

In the substrate for an electro-optical device according to the application example described above, it is preferable that the third slopes include slopes which are arranged so as to be plane-symmetric with respect to a plane orthogonal to the first surface, and the slopes that are arranged so as to be plane-symmetric be connected in a direction from the first surface to the second surface.

The slopes (third slopes) that are arranged so as to be plane-symmetric with respect to a plane orthogonal to the first surface are connected in a direction from the first surface side towards the second surface side, and thus the groove described above is formed. Then, a bottom (bottom side) of a pointed shape in a direction from the first surface side towards the second surface side is formed on the second surface side of the groove. For example, if the bottom of the region widening in a direction along the first surface is formed on the second surface side of the groove, light is reflected on the region widening in a direction along the first surface, incidence of light to the slopes of the groove being the light reflection surface is inhibited, and thus the utilization efficiency of the light is reduced. If the bottom of the groove has a pointed shape in a direction from the first surface side towards the second surface side, incidence of light to the slopes of the groove being the light reflection surface is less likely to be inhibited, and it is possible to improve the utilization efficiency of light. Accordingly, it is preferable that the slopes (third slopes) that are arranged so as to be plane-symmetric with respect to a plane orthogonal to the first surface are connected in a direction from the first surface side towards the second surface side.

### APPLICATION EXAMPLE 5

In the substrate for an electro-optical device according to the application example, it is preferable that the first insulating film be a silicon oxide that is formed by plasma CVD using tetraethoxysilane gas.

The silicon oxide formed by plasma CVD using tetraethoxysilane gas is excellent in step coverage, and is capable of easily covering the substrate having the above-described previous-stage groove provided, in other words, the inside of the previous-stage groove. Accordingly, the silicon oxide formed by plasma CVD using tetraethoxysilane covers the entire region (the first slopes and the second slopes) of the previous-stage groove, and a groove being a light reflection portion is easily formed.

### APPLICATION EXAMPLE 6

In the substrate for an electro-optical device according to the application example described above, it is preferable that the substrate, the first insulating film, and the second insulating film have approximately the same refractive index, and the refractive index of a region surrounded by the groove and the second insulating film be smaller than the refractive index of the substrate.

Since the substrate, the first insulating film, and the second insulating film have approximately the same refractive index, light is satisfactorily transmitted through the interface between the substrate and the first insulating film, and the interface between the first insulating film and the second insulating film. Since the refractive index of the region surrounded by the groove and the second insulating film is smaller than the refractive index of the substrate (first insulating film), it is possible to form the light reflection surface at the interface between the region surrounded by the groove and the second insulating film, and the first insulating film. Accordingly, it is possible to form a substrate for an electro-optical device for which the interface between the region surrounded by the groove and the second insulating film, and the first insulating film is the light reflection surface.

### APPLICATION EXAMPLE 7

According to this application example, there is provided an electro-optical device including: a first substrate including pixel electrodes, and transistors that drive the pixel electrodes; and a second substrate that is arranged so as to face the first substrate. At least one of the first substrate and the second substrate includes the substrate for an electro-optical device according to the application examples described above.

It is possible to improve the utilization efficiency of light in the electro-optical device, and realize a bright display, by forming components modulating light of the electro-optical device and components emitting light thereof in the substrate for an electro-optical device having the light reflecting portion provided.

### APPLICATION EXAMPLE 8

According to this application example, there is provided an electronic equipment including the electro-optical device according to the application examples described above.

The electronic equipment according to the present application example includes the electro-optical device described in the above applications, and the light reflecting portion provided in the substrate for an electro-optical device realizes bright display in the electro-optical device. It is possible to provide bright display, by applying the electro-optical device described in the above applications to, for example, a projection type display apparatus, an information terminal device such as a projection type head-up display (HUD), a direct-view-type head mounted display (HMD), an e-book, a personal computer, a digital still camera, an LCD TV, a viewfinder type or monitor direct-view-type video recorder, a car navigation system, and a POS, and electronic equipment such as an electronic organizer.

### APPLICATION EXAMPLE 9

According to this application example, there is provided a manufacturing method for the substrate for an electro-optical device according to the application examples described above, including: accumulating a mask on the first surface of the substrate; forming an opening surrounded by a wall surface in which the substrate is exposed, by performing anisotropy etching on the mask; performing anisotropy etching on the substrate which is exposed in the opening, while etching the mask so that the wall surface retracts; removing the mask; and forming a groove by accumulating a silicon oxide by plasma CVD using tetraethoxysilane gas.

It is possible to form a previous-stage groove of a large longitudinal dimension (depth), by forming a mask having a region surrounded by the wall surface in which the substrate is exposed, with a material having high etching selectivity with respect to the substrate, and etching the substrate in a longitudinal direction (normal direction) by using the mask as an etching mask. It is possible to form a previous-stage groove having a region (opening region) that is widened more on the first surface side of the substrate, by etching the substrate in the longitudinal direction, while etching the mask so that the wall surface retracts in a direction crossing the normal direction, in other words, while increasing the size of the region for etching the substrate in the lateral direction. Since the previous-stage groove is widened on the first surface side of the substrate, a material forming a silicon oxide easily enters the previous-stage groove. Further, a silicon oxide formed by plasma CVD using tetraethoxysilane is excellent in step coverage. As a result, the silicon oxide formed by plasma CVD using tetraethoxysilane covers the entire region (the first slopes and the second slopes) of the previous-stage groove, and thus it is possible to easily form the groove which is the light reflection portion.

### APPLICATION EXAMPLE 10

In the method for manufacturing a substrate for an electro-optical device according to the application example described above, it is preferable that a forming material of the substrate be quartz, and a forming material of the mask be either a tungsten silicide or silicon.

Tungsten silicide or silicon has high etching selectivity with respect to quartz (a silicon oxide). Accordingly, it is possible to form a previous-stage groove of a large longitudinal dimension (depth), by etching the substrate (a silicon oxide) in the longitudinal direction using tungsten silicide or silicon as a mask (etching mask).

### APPLICATION EXAMPLE 11

According to this application example, there is provided a method for manufacturing an electro-optical device, including: accumulating a mask on a first surface of a substrate; forming an opening on the mask forming a first groove having first slopes and second slopes by performing anisotropy etching on the substrate from the opening side; removing the mask; forming a first insulating film that covers the first slopes and the second slopes; and forming a second insulating film that covers the first groove and the first insulating film. The second slopes rather than the first slopes are arranged on the first surface side. A part of the second insulating film that covers the groove has a set distance with the third slopes being surfaces of the first insulating film which covers the first slopes. Each of angles that the second slopes make with a normal line of the first surface is greater than each of angles that the first slopes make with the normal line.

According to the present application examples, it is possible to form a structure suitable for the prism by covering the first slopes and the second slopes with the first insulating film.

### BRIEF DESCRIPTION OF DRAWINGS

FIG. 1 is a schematic plan view illustrating the configuration of a liquid crystal device according to Embodiment 1.

FIG. 2 is a schematic cross-sectional view taken along line J-J′ in FIG. 1.

FIG. 3 is an equivalent circuit diagram illustrating an electrical configuration of the liquid crystal device according to Embodiment 1.

FIG. 4 is a schematic plan view illustrating the arrangement of pixel electrodes.

FIG. 5 is a schematic cross-sectional view of the liquid crystal device taken along line A-A′ in FIG. 4.

FIG. 6 is a schematic cross-sectional view of a region C surrounded with a broken line in FIG. 5.

FIG. 7 is a process flow for forming a substrate for an electro-optical device.

FIG. 8 is a schematic cross-sectional view illustrating a state of the substrate for an electro-optical device after passing through respective steps.

FIG. 9 is a schematic cross-sectional view illustrating a state of the substrate for an electro-optical device after passing through respective steps.

FIG. 10 is a schematic cross-sectional view illustrating a state of the substrate for an electro-optical device after passing through respective steps.

FIG. 11 is a schematic cross-sectional view of a liquid crystal device according to Embodiment 2.

FIG. 12 is a schematic diagram illustrating the configuration of a projection type display apparatus according to Embodiment 3.

### DESCRIPTION OF EMBODIMENTS

Hereinafter, embodiments of the present invention will be described with reference to the drawings. Such embodiments are intended to illustrate one aspect of the present invention, but are not intended to limit the present invention, and can be changed arbitrarily within the scope of the technical idea of the present invention. Further, in each of the following drawings, since respective layers and respective portions are illustrated as recognizable dimensions in the drawings, the scales of respective layers and respective portions may be different from the real dimensions.

### Embodiment 1

“Overview of Liquid Crystal Device”

A liquid crystal device 100 according to Embodiment 1 is an example of an electro-optical device, and is a transmission type liquid crystal device including a thin film transistor (hereinafter, referred to as a TFT) 30. The liquid crystal device 100 according to the present embodiment can be suitably used as an optical modulation device of a projection type display apparatus (liquid crystal projector) which will be described later.

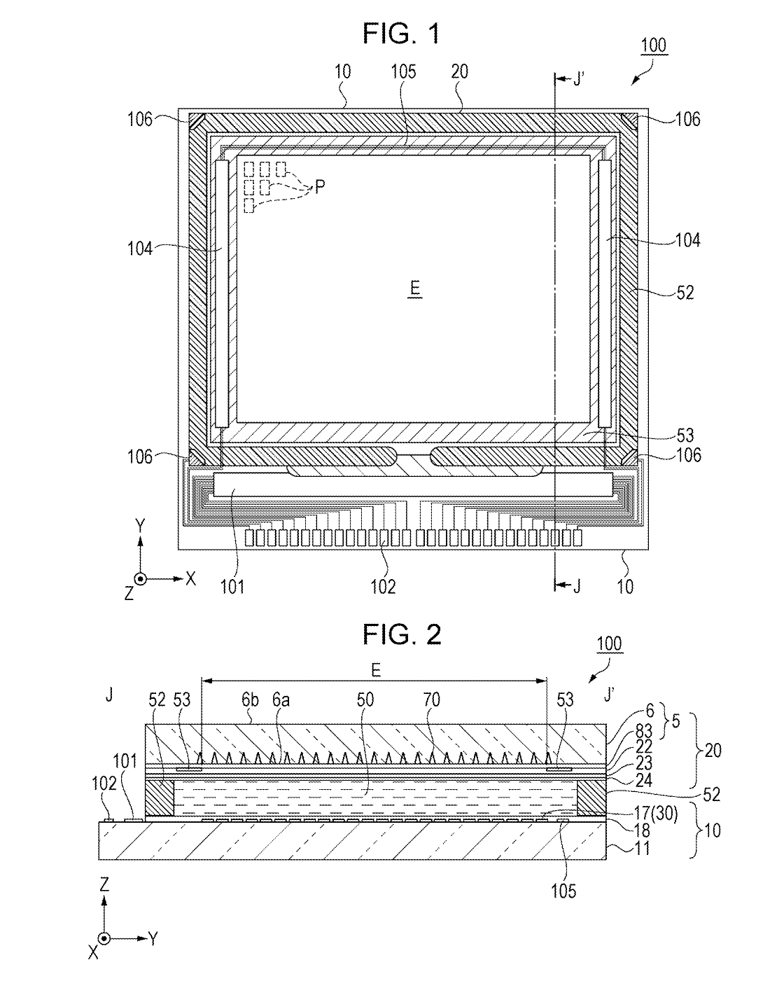

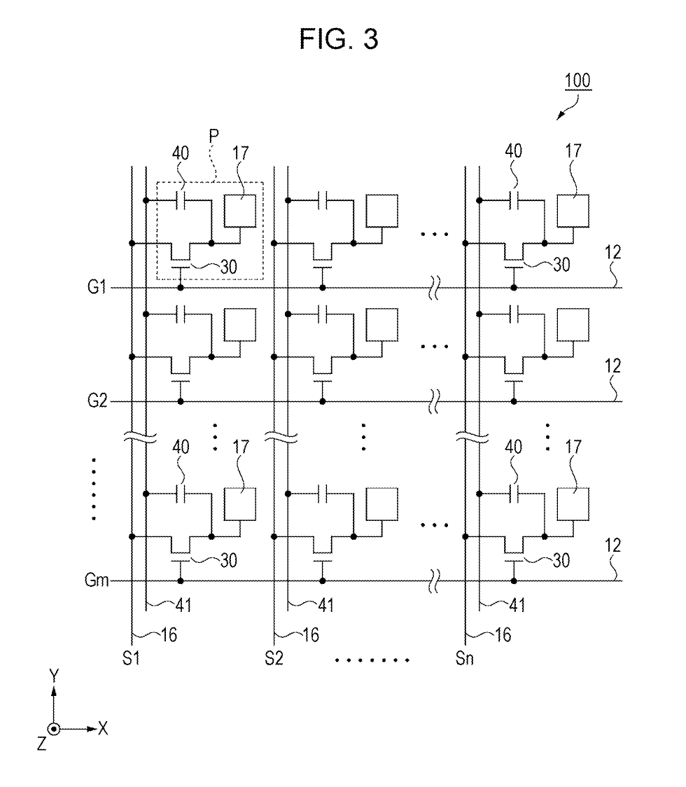

First, the overall configuration of the liquid crystal device 100 according to the present embodiment will be described with reference to FIG. 1 to FIG. 3. FIG. 1 is a schematic plan view illustrating the configuration of the liquid crystal device. FIG. 2 is a schematic cross-sectional view taken along line J-J′ in FIG. 1. FIG. 3 is an equivalent circuit diagram illustrating an electrical configuration of the liquid crystal device.

As illustrated in FIG. 1 and FIG. 2, the liquid crystal device 100 according to the present embodiment includes an element substrate 10, a counter substrate 20, a liquid crystal layer 50 interposed between the element substrate 10 and the counter substrate 20, and the like.

The element substrate 10 is an example of “first substrate” in the present invention. The counter substrate 20 is an example of “second substrate” in the present invention.

The element substrate 10 is larger than the counter substrate 20, and a liquid crystal layer 50 is made by bonding two substrates through a sealing member 52 arranged in a frame shape, and sealing a liquid crystal having positive or negative dielectric anisotropy in a gap. For example, an adhesive such as thermosetting or ultraviolet-curable epoxy resin is employed as the sealing member 52. Spacers (not shown) for maintaining a distance between a pair of substrates are mixed in the sealing member 52.

A light shielding film 53 is provided in a frame shape on the inner side of the sealing member 52 which is arranged in a frame shape. The light shielding film 53 is made from, for example, light shielding metal, metal oxides, or the like, and the inner side of the light shielding film 53 is a display region E. A plurality of pixels P are arranged in a matrix form in the display region E.

A data line driving circuit 101 is provided between a first surface of the element substrate 10, in which a plurality of external connection terminals 102 are arranged, and the sealing member 52 arranged along the first surface. Scanning line driving circuits 104 are provided between the sealing members 52, which are respectively arranged along a second side and a third side being perpendicular to the first surface and opposed to each other, and the display region E. A plurality of wirings 105 connecting two scanning line driving circuits 104 are provided between the sealing member 52 arranged along a fourth side facing the first surface and the display region E. The wirings connected to the data line driving circuit 101 and the scanning line driving circuit 104 are coupled to a plurality of external connection terminals 102 which are arranged along the first surface.

Hereinafter, a description will be made assuming that a direction along the first surface is an X direction, a direction along two separate sides (the second surface and the third side) which are perpendicular to the first surface and opposed to each other is a Y direction, and a direction from the element substrate 10 towards the counter substrate 20 is a Z direction.

In addition, the Z direction is an example of “normal line of the first surface” in the present invention. Hereinafter, “normal line of the first surface” in the present invention is referred to as the Z direction or the normal line.

As illustrated in FIG. 2, the element substrate 10 includes an element substrate main body 11, a TFT 30 and a pixel electrode 17 which are formed on the surface on the liquid crystal layer 50 side of the element substrate main body 11, and an alignment film 18 which covers the pixel electrode 17. The element substrate main body 11 is made from, for example, a transparent material such as quartz or glass. In addition, the TFT 30 and the pixel electrode 17 are components of the pixel P.

Details of the element substrate 10 will be described later.

The counter substrate 20 includes a substrate 5 for an electro-optical device, and a light shielding film 53, an insulating film 22, a counter electrode 23, and an alignment film 24, which are stacked in order on a surface on the liquid crystal layer 50 side of the substrate 5 for an electro-optical device.

The substrate 5 for an electro-optical device includes a substrate main body 6, a prism 70, a third insulating film 83, and the like.

For example, a quartz substrate is used for the substrate main body 6. The substrate main body 6 may be a transparent insulating substrate, and a glass substrate, a sapphire substrate, or the like other than the quartz substrate may be used for the substrate main body 6. A prism 70 is formed on a surface 6a on the liquid crystal layer 50 side of the substrate main body 6. Furthermore, the surface on the liquid crystal layer 50 side of the substrate main body 6 having the prism 70 provided therein is covered with a third insulating film 83. The third insulating film 83 is made from, for example, a silicon oxide. Further, the substrate main body 6 has the surface 6a on the liquid crystal layer 50 side and a surface 6b facing the surface 6a on the liquid crystal layer 50 side.

The substrate main body 6 is an example of “substrate which transmits light” in the present invention. The surface 6a on the liquid crystal layer 50 side of the substrate main body 6 is an example of the “first surface” in the present invention, and is referred to as a front surface 6a, hereinafter. Further, the surface 6b facing the surface 6a on the liquid crystal layer 50 side of the substrate main body 6 is an example of the “second surface” in the present invention, and is referred to as a back surface 6b, hereinafter.

Details of the substrate 5 for an electro-optical device will be described later.

The light shielding film 53 is made from, for example, a metal or a metal oxide with light-shielding properties. As illustrated in FIG. 1, the light shielding film 53 is formed in a frame shape at a position overlapping the scanning line driving circuit 104 on a plane. The light shielding film 53 shields light incident on the element substrate 10 from the counter substrate 20, and prevents a malfunction due to light of the scanning line driving circuit 104. Further, the light shielding film 53 prevents unnecessary stray light from entering the display region E, and this ensures a high contrast in the display of the display region E.

The insulating film 22 is made from a transmissive inorganic insulating material, and for example, a silicon oxide formed by using an atmospheric pressure CVD or a reduced pressure CVD method can be used. The insulating film 22 has enough of a film thickness to relax surface unevenness caused by forming the light shielding film 53 on the substrate 5 for an electro-optical device.

The counter electrode 23 is made from, for example, a transparent conductive film such as an Indium Tin Oxide (ITO), and formed over the display region E. As illustrated in FIG. 1, the counter electrode 23 is electrically connected to the wiring on the element substrate 10 side by a vertical conductive portion 106 which is provided at four corners of the counter substrate 20.

The alignment film 18 which covers the pixel electrode 17 and the alignment film 24 which covers the counter electrode 23 are set based on the optical design of the liquid crystal device 100; and in the present embodiment, an oblique deposition film (inorganic alignment film) of an inorganic material such as a silicon oxide is used. Further, an organic alignment film such as polyimide may be used for the alignment film 18 and 24.

As illustrated in FIG. 3, the liquid crystal device 100 includes a plurality of scan lines 12 and a plurality of data lines 16 as signal lines which are insulated from each other and perpendicular to each other at least in the display region E, capacity lines 41 which extend parallel to the data lines 16, and the like. In addition, the arrangement of the capacity lines 41 is not limited thereto, and may be arranged so as to extend parallel to the scan lines 12.

In addition, the scan lines 12, the data line 16, and the capacity lines 41 are made from a light-shielding conductive material, and are provided on the element substrate 10 side.

The pixel electrode 17, the TFT 30, a storage capacitor 40, and the like are provided in a region partitioned by the scan line 12 and the data line 16, and constitute a pixel circuit of the pixel P.

The scan line 12 is electrically connected to the gate electrode of the TFT 30. The data line 16 is electrically connected to the source electrode of the TFT 30. The pixel electrode 17 is electrically connected to the drain electrode of the TFT 30.

The data line 16 is connected to the data line driving circuit 101 (see FIG. 1), and supplies each pixel P with image signals S1, S2, . . . , Sn which have been supplied from the data line driving circuit 101. The scan line 12 is connected to the scanning line driving circuit 104 (see FIG. 1), and supplies each pixel P with scan signals G1, G2, . . . , Gn which have been supplied from the scanning line driving circuit 104. The image signals S1, S2, . . . , Sn which have been supplied from the data line driving circuit 101 to the data line 16 may be supplied in order in a line sequential manner, or may be supplied to each group that is made by grouping a plurality of data lines 16 which are adjacent to each other.

The liquid crystal device 100 is configured in such a manner that the image signals S1, S2, . . . , Sn supplied from the data lines 16 are written into the pixel electrode 9 through the TFT 30 in synchronism with a period in which the TFT 30 which is a switching element is turned on by the input of the scan signals G1, G2, . . . , Gm. Then, the image signals S1, S2, . . . , Sn of a predetermined level which are written into the pixel electrode 17 are held for a certain period between the pixel electrode 17 and the counter electrode 23 functioning as a common electrode.

In order to prevent the held image signals S1, S2, . . . , Sn from leaking (degrading), the storage capacitor 40 is connected in parallel with a liquid crystal capacitor formed between the pixel electrode 17 and the counter electrode 23. The storage capacitor 40 is provided between the drain electrode of the TFT 30 and the capacity line 41.

Such a liquid crystal device 100 is a transmissive type, and employs an optical design of a normally white mode in which the transmittance of the pixel P when a voltage is not applied is greater than the transmittance when a voltage is applied and is a bright display, and a normally black mode in which the transmittance of the pixel P when a voltage is not applied is smaller than the transmittance when a voltage is applied and is a dark display. Depending on the optical design, polarizing elements (not shown) are respectively arranged and used in the incident side and the exit side of light.

“Overview of Element Substrate and the Substrate for an Electro-Optical Device”

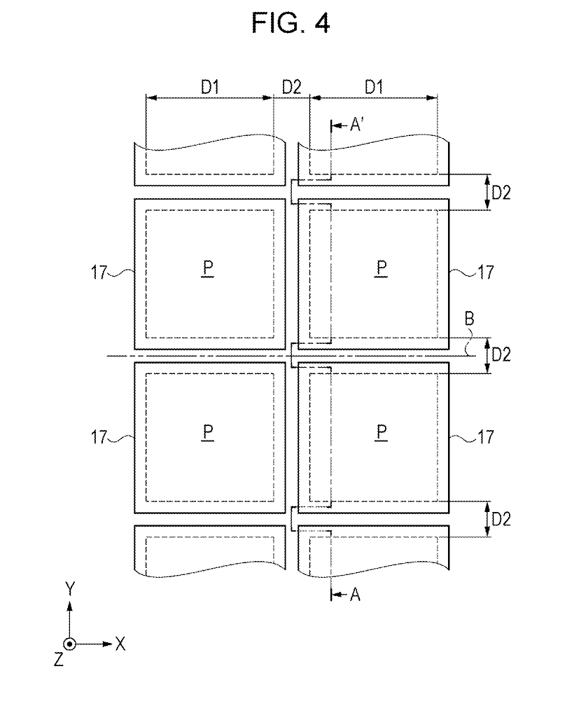

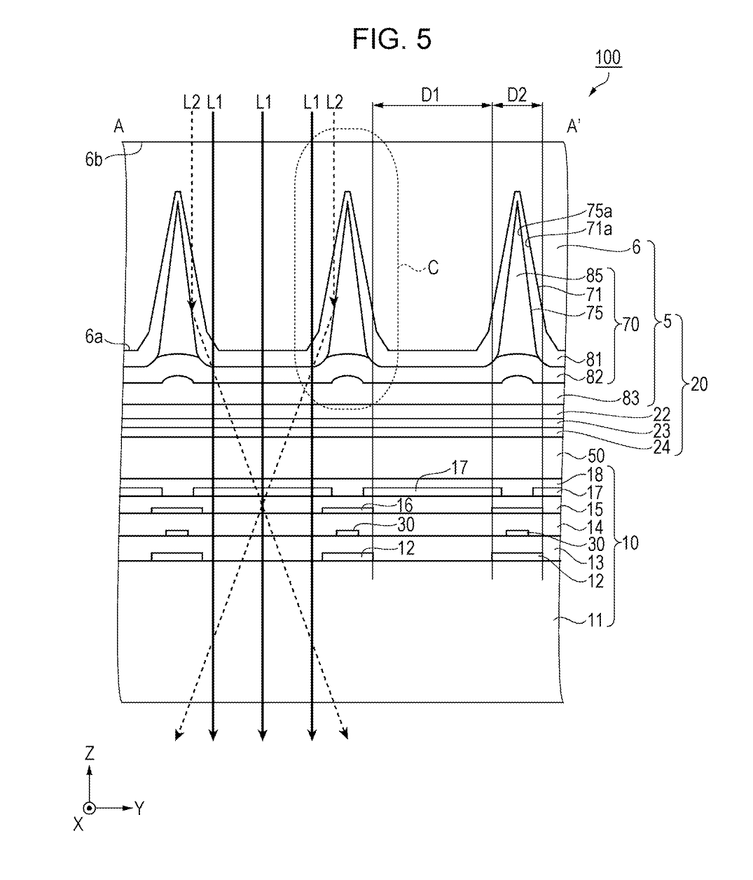

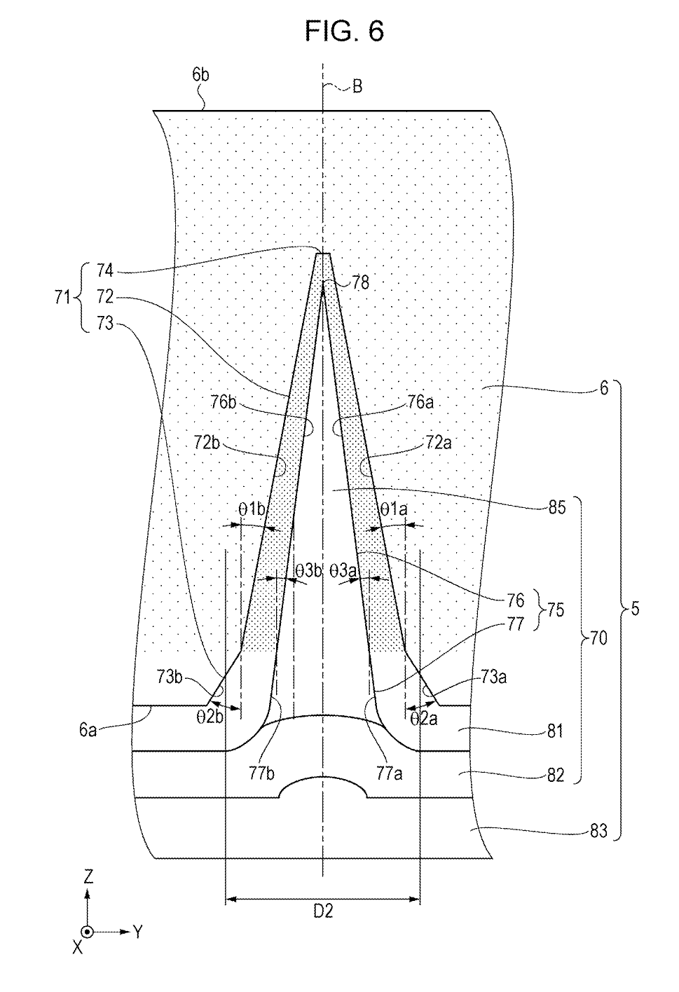

FIG. 4 is a schematic plan view illustrating the arrangement of the pixel electrodes. FIG. 5 is a schematic cross-sectional view of the liquid crystal device taken along line A-A′ in FIG. 4. FIG. 6 is a schematic cross-sectional view of a region C surrounded with a broken line in FIG. 5. B indicated by a two-dot chain line in FIG. 4, and FIG. 6 represents a plane (a plane formed in the X direction and the Z direction) perpendicular to a center line of the non-opening region D2 which extends in the X direction, and hereinafter is referred to as a reference plane B. In addition, the reference plane B is an example of “plane perpendicular to the first surface (a plane formed in the X direction and the Y direction)”. Further, in FIG. 6, in order to clarify the drawing, a region, in which upper grooves 72 and 76 to be described later are arranged, is indicated by being shaded.

Below, with reference to FIG. 4 to FIG. 6, the overview of the element substrate 10 and the substrate 5 for an electro-optical device will be described.

As illustrated in FIG. 4, pixels P are arranged in a matrix form in the X direction and the Y direction.

A non-opening region D2 is a light-shielding region including signal lines (the data line 16, the scan line 12, and the capacity line 41) with light-shielding properties provided on the element substrate 10 side, a light shielding film 53 provided on the counter substrate 20 side, and the like. The non-opening region D2 extends in the X direction and the Y direction, and is provided in a matrix form. The width of the non-opening region D2 is the same in the X direction and the Y direction. A region surrounded by the non-opening region D2 is an opening region D1 which transmits light (light is modulated). The opening region D1 is partitioned into a square (substantially square) in the non-opening region D2.

The pixel electrode 17 is provided for each pixel P, and has a rectangular shape (substantially square). As viewed from the Z direction, the outer edge of the pixel electrode 17 is arranged so as to overlap the non-opening region D2 with light-shielding properties. Although not illustrated in FIG. 4, the TFT 30, the storage capacitor 40, the prism 70, and the like are arranged in the non-opening region D2.

First, an overview of the element substrate 10 will be described.

As illustrated in FIG. 5, the element substrate 10 includes an element substrate main body 11, and a scan line 12, an insulating layer 13, a TFT 30, an insulating layer 14, a data line 16, an insulating layer 15, a pixel electrode 17, an alignment film 18, and the like, which are stacked on the surface on the liquid crystal layer 50 side of the element substrate main body 11 in order.

The scan line 12 is made from, for example, single metal, an alloy, metal silicide, poly silicide, or nitride consisting of at least one metal material such as aluminum (Al), molybdenum (Mo), tungsten (W), titanium (Ti), tantalum (Ta), chromium (Cr), or a multi-layered film thereof, and has light-shielding properties.

The insulating layer 13 is provided so as to cover the element substrate main body 11 and the scan line 12. The insulating layer 13 is made from, for example, a silicon oxide, and has optical transparency. The TFT 30 is provided on the insulating layer 13. The TFT 30 is a switching element which drives the pixel electrode 17. Although not illustrated, the TFT 30 includes a semiconductor layer, a gate electrode, a source electrode, and a drain electrode.

The semiconductor layer is made from, for example, polycrystalline silicon film, and is formed in an island shape. Impurity ions are implanted on the semiconductor layer so as to form a source region, a channel region, and a drain region. A Lightly Doped Drain (LDD) region may be formed between the channel region and the source region, or between the channel region and the drain region.

The gate electrode is arranged over a portion of the insulating layer 14 (gate insulating film) in a region overlapping the channel region of the semiconductor layer as viewed from the Z direction. Although not illustrated, the gate electrode is electrically connected to the scan line 12 that is arranged on the lower layer side through the contact hole.

The insulating layer 14 is provided so as to cover the insulating layer 13 and the TFT 30. The insulating layer 14 is made from, for example, a silicon oxide, and has optical transparency. The insulating layer 14 includes a gate insulating film for insulation between the semiconductor layer and the gate electrode of the TFT 30. The insulating layer 14 mitigates surface irregularities caused by the TFT 30.

The data line 16 is provided on the insulating layer 14. The data line 16 is made from the same material as the scan line 12, and has light-shielding properties. The TFT 30 is arranged so as to be interposed between the scan line 12 with light-shielding properties and the data line 16. This suppresses an increase in a leak current (malfunction of the TFT 30) due to light incident on the semiconductor layer of the TFT 30.

Although not illustrated, above the insulating layer 14, the capacity line 41 is provided by varying the data line 16 and the wiring layer. The insulating layer 15 is provided so as to cover the insulating layer 14, the data line 16, and the capacity line 41. The insulating layer 15 is made from, for example, a silicon oxide, and has optical transparency.

The pixel electrode 17 is provided on the insulating layer 15. The pixel electrode 17 is electrically connected to the drain region in the semiconductor layer of the TFT 30, through contact holes (not illustrated) provided in the insulating layer 14 and the insulating layer 15. The alignment film 18 is provided so as to cover the pixel electrode 17.

Next, an overview of the substrate 5 for an electro-optical device will be described.

As illustrated in FIG. 5, the substrate 5 for an electro-optical device includes the substrate main body 6, the prism 70 provided on the front surface 6a of the substrate main body 6, the third insulating film 83 that covers the prism 70, and the like.

As described above, the substrate main body 6 is a substrate that transmits light, and in the present embodiment, a quartz substrate is used.

The prism 70 includes a first groove 71 that is formed by etching the substrate main body 6, a first insulating film 81 that covers the first groove 71, a second groove 75, a second insulating film 82 that closes the opening of the second groove 75, an air layer 85 that is sealed with the second groove 75 and the second insulating film 82, and the like.

The first insulating film 81 and the second insulating film 82 are made from, for example, a silicon oxide, and have optical transparency. The second groove 75 is formed by covering the first groove 71 with the first insulating film 81. The second groove 75 has a shape widening in a direction toward the front surface 6a of the substrate main body 6 from the back surface 6b thereof, in other words, in the Z(−) direction.

The second groove 75 is an example of “groove” in the present invention. The first insulating film 81 is an example of “first insulating film” in the present invention. The second insulating film 82 is an example of “second insulating film” in the present invention.

Further, the first groove 71 is a groove in a stage prior to formation of the second groove 75, in other words, a groove in a stage prior to formation of the “groove” in the present invention.

The air layer 85 having a lower refractive index than the refractive index of the substrate main body 6 is located in the region surrounded by the second groove 75 and the second insulating film 82. Further, the substrate main body 6 (quartz), the first insulating film 81 (a silicon oxide), the second insulating film 82 (a silicon oxide), and the third insulating film 83 (a silicon oxide) are made from materials having approximately the same refractive index, and light is satisfactorily transmitted through interfaces between regions in which these materials are stacked while the attenuation of light occurs due to reflection or the like of light at the interface (boundary) of these materials.

Meanwhile, light is reflected on the slope 75a of the second groove 75, in other words, at an interface between the air layer 85 and the first insulating film 81, which have different refractive index.

In FIG. 5, the arrows denoted by symbols L1 and L2 represent light that is emitted from a light source (not illustrated) and incident on the element substrate 10 side from the counter substrate 20 side (hereinafter, referred to as incident light). Incident light L1 indicated by a solid line is light that is incident (travels) to the opening region D1, and incident light L2 indicated by a broken line is light that travels to the non-opening region D2. The liquid crystal device 100 in the present embodiment is an optical modulation element (light valve) that can be suitably used for a liquid crystal projector which will be described later, and light that is emitted from a light source is intended to be incident on the element substrate 10 side from the counter substrate 20. The light incident on the liquid crystal device 100 is light that is modulated in the opening region D1, emitted in the Z(−) direction and displayed.

As illustrated in FIG. 5, the incident light L1 traveling to the opening region D1 becomes display light by being passed through the opening region D1 and emitted in the Z(−) direction. The incident light L2 traveling to the non-opening region D2 becomes display light by being reflected from the prism 70 (the slope 75a of the second groove 75), passed through the opening region D1 and emitted in the Z(−) direction.

In this manner, since the incident light L2 traveling to the non-opening region D2 can also be used as display light as well as the incident light L1 traveling to the opening region D1 by the prism 70, it is possible to improve the utilization efficiency of the incident light as compared to the case of not forming the prism 70, and thus a bright display is realized.

In addition, even when light emitted from the light source is incident on the counter substrate 20 side from the element substrate 10 side, it is possible to improve the utilization efficiency of the incident light by the prism 70.

“Configuration of Prism”

Next, with reference to FIG. 6, the configuration of the prism 70 will be described in detail. As described above, the prism 70 includes a first groove 71, a first insulating film 81, a second groove 75, a second insulating film 82, an air layer 85, and the like.

As illustrated in FIG. 6, the first groove 71 includes an upper groove 72, a lower groove 73, and a bottom surface 74. The first groove 71 has a shape widening in a direction from the back surface 6b of the substrate main body 6 towards the front surface 6a of the substrate main body 6, in other words, in the Z(−) direction.

The upper groove 72 has first slopes 72a and 72b which are arranged so as to be substantially plane-symmetric with respect to the reference plane B. The lower groove 73 includes second slopes 73a and 73b which are arranged so as to be substantially plane-symmetric with respect to the reference plane B. The lower groove 73 is arranged on the front surface 6a of the substrate main body 6 side rather than the upper groove 72. The second slopes 73a and 73b rather than the first slopes 72a and 72b are arranged on the front surface 6a side of the substrate main body 6.

In the following description, the angle that each of the slopes such as the first slopes 72a and 72b and the second slopes 73a and 73b makes with the normal line (Z direction) is referred to as a tilt angle.

The tilt angles θ2a and θ2b of the second slopes 73a and 73b are greater than the tilt angles θ1a and θ1b of the first slopes 72a and 72b. Specifically, the tilt angles θ2a and θ2b of the second slopes 73a and 73b are in the range from 4 degrees to 7 degrees, and the tilt angles θ1a and θ1b of the first slopes 72a and 72b are in the range from 1 degree to 3 degrees.

In addition, the slope in the present embodiment includes a curved surface in addition to a plane. In other words, the angle (tilt angle) that the slope makes with the normal line in the present embodiment may be constant in some cases and not constant in other cases.

The bottom surface 74 is the bottom of the first groove 71, and has a shape widening in the Y direction. As will be described in detail later, the first groove 71 is formed by etching the substrate main body 6. The bottom surface 74 is a region that reacts with etching gas, when etching the substrate main body 6 in a depth direction (normal direction). As described above, since the interface between the substrate main body 6 and the first insulating film 81 has optical transparency, even when a region widening in the Y direction (bottom surface 74) is formed in the bottom of the first groove 71, the bottom surface 74 will not affect the transmittance of the light (incident light L1 and incident light L2).

The second groove 75 includes an upper groove 76, a lower groove 77, and a bottom 78. The second groove 75 has a shape widening in a direction from the back surface 6b of the substrate main body 6 towards the front surface 6a of the substrate main body 6, in other words, in the Z(−) direction.

The upper groove 76 has third slopes 76a, 76b which are arranged so as to be substantially plane-symmetric with respect to the reference plane B. The lower groove 77 includes fourth slopes 77a, 77b which are arranged so as to be substantially plane-symmetric with respect to the reference plane B. The lower groove 77 is arranged on the front surface 6a of the substrate main body 6 side rather than the upper groove 76. The fourth slopes 77a, 77b are arranged on the front surface 6a side of the substrate main body 6 rather than the third slopes 76a, 76b.

As described above, the second groove 75 is formed by covering the first groove 71 with the first insulating film 81. Accordingly, the front surfaces of the first insulating film 81 that covers the first slopes 72a and 72b of the first groove 71 are the third slopes 76a, 76b of the second groove 75. The front surfaces of the first insulating film 81 that covers the second slopes 73a and 73b of the first groove 71 are the fourth slopes 77a, 77b of the second groove 75. The tilt angles θ3a and θ3b of the third slopes 76a, 76b are smaller than the tilt angles θ1a and θ1b of the first slopes 72a and 72b. Specifically, the tilt angles θ3a and θ3b of the third slopes 76a, 76b are set to be smaller than 3 degrees.

The third slopes 76a and the third slopes 76b are connected in a direction from the front surface 6a side of the substrate main body 6 towards the back surface 6b side of the substrate main body 6, and the bottom side 78 (the bottom of the second groove 75) along the X direction is formed. If seen from the X direction, the bottom of the second groove 75 has a sharp shape in the Z direction. The bottom of the second groove 75 does not have a shape widening in the Y direction. As will be described in detail later, the second groove 75 is formed by accumulating the first insulating film 81 in the first groove 71 and covering the first groove 71 with the first insulating film 81. In the process of accumulating the first insulating film 81 in the first groove 71, the sharp shape in the Z direction can be easily formed.

As described above, the slopes 75a (the third slopes 76a and 76b and the fourth slopes 77a and 77b) of the second groove 75 are interfaces made from materials having different refractive indexes (the first insulating film 81 and the air layer 85), and a light reflection surface. If a region widening in the Y direction is present in the bottom of the second groove 75, reflection of light occurs in the region widening in the Y direction, reflection of light in the Z(−) direction (the reflection of light in the direction to be display light) is inhibited, and thus the utilization efficiency of the light of the liquid crystal device 100 is reduced. Unlike the first groove 71, since the bottom 78 of the second groove 75 does not include the region widening in the Y direction, the utilization efficiency of the light (the incident light L1 and the incident light L2) due to the reflection of light is suppressed. Further, the bottom 78 of the second groove 75 may have a slightly widened region.

The slopes 71a of (the first slopes 72a and 72b, and the second slopes 73a and 73b) the first groove 71 and the slopes 75a (the third slopes 76a and 76b and the fourth slopes 77a and 77b) of the second groove 75 are arranged so as to be substantially plane-symmetric with respect to the reference plane B, but are not limited thereto. For example, even when the third slopes 76a and the third slopes 76b of the second groove 75 are not arranged so as to be substantially plane-symmetric with respect to the reference plane B and the tilt angle θ3a of the third slope 76a and the tilt angle θ3b of the third slope 76b are different from each other, if the tilt angle θ3a of the third slope 76a and the tilt angle θ3b of the third slope 76b are smaller than 3 degrees, it is possible to obtain an excellent effect of increasing the utilization efficiency of the light of the liquid crystal device 100.

Similarly, the tilt angle θ2a of the second slope 73a and the tilt angle θ2b of the second slope 73b may be different from each other, and the tilt angle θ2a of the second slope 73a and the tilt angle θ2b of the second slope 73b may be in the range from 4 degrees to 7 degrees. Further, the tilt angle θ1a of the first slope 72a and the tilt angle θ1b of the first slope 72b may be different from each other, and the tilt angle θ1a of the first slope 72a and the tilt angle θ1b of the first slope 72b may be in the range from 1 degree to 3 degrees.

The second insulating film 82 is arranged at a position away from the third slopes 76a and 76b of the second groove 75, and is formed by closing the opening of the second groove 75 and covering the first insulating film 81. As will be described in detail later, in the process of forming the second insulating film 82, the air layer 85 (a region filled with material having lower refractive index than that of substrate main body 6) is formed in a region surrounded with the second groove 75 and the second insulating film 82.

In this manner, the prism 70 is arranged on the non-opening region D2, has a function as a light reflection portion, reflects the light traveling to the non-opening region D2 to the opening region D1, and has a role to improve the utilization efficiency of the liquid crystal device 100. The light reflection surfaces of the prism 70 are third slopes 76a and 76b of the second groove 75. The tilt angles of the light reflection surfaces (third slopes 76a and 76b) are preferably 3 degrees or less. Further, the tilt angles of the light reflection surfaces (third slopes 76a and 76b) are preferably small.

A manufacturing method according to the present invention has a configuration suitable for stably forming the prism 70 having more preferable light reflection surfaces. Hereinafter, the overview will be described.

“A Method for Manufacturing a Substrate for an Electro-Optical Device”

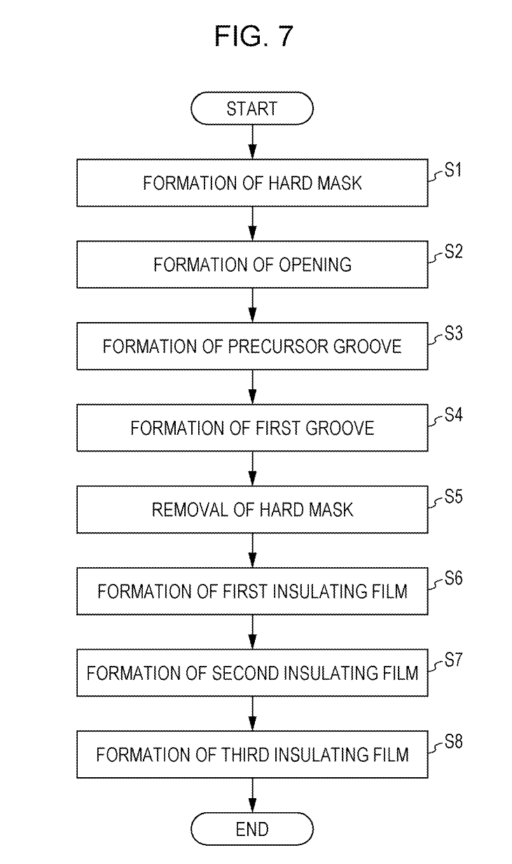

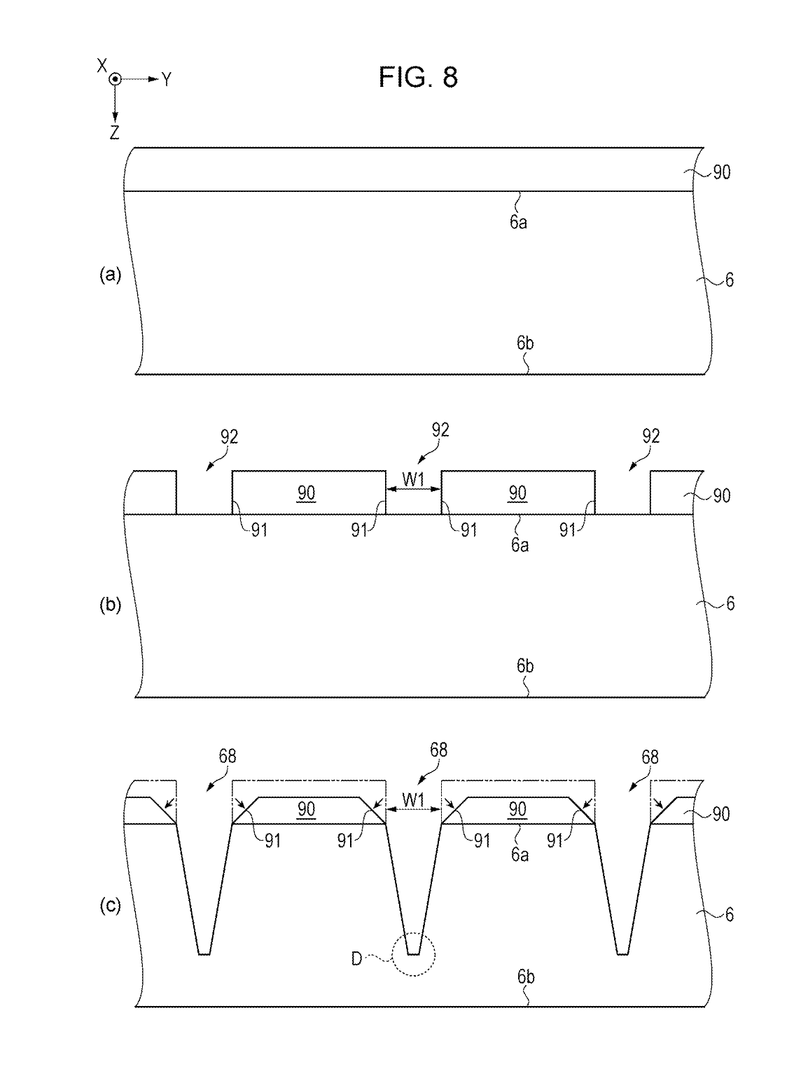

FIG. 7 is a process flow for forming the substrate for an electro-optical device. FIG. 8 to FIG. 10 correspond to FIG. 5, and are schematic cross-sectional views illustrating the states of the substrate for an electro-optical device after passing through respective steps illustrated in FIG. 7. In addition, in order to clarify the drawings, the positional relationships between the front surface 6a and the back surface 6b of the substrate main body 6 in FIG. 8 to FIG. 10 are different from the positional relationship between the front surface 6a and the back surface 6b of the substrate main body 6 in FIG. 5 (they are reversed). Specifically, in FIG. 8 to FIG. 10, the front surface 6a of the substrate main body 6 is arranged above the back surface 6b of the substrate main body 6.

Hereinafter, with reference to FIG. 7 to FIG. 10, a method for manufacturing a substrate for an electro-optical device will be described.

In step S1 of FIG. 7, a hard mask 90 is formed by accumulating tungsten silicide on the front surface 6a of the substrate main body 6, by using known techniques such as sputtering and chemical vapor deposition (CVD). The film thickness of the hard mask 90 is approximately 2000 nm to 4000 nm. The hard mask 90 is made from material having high etching selectivity with respect to the substrate main body 6, when etching the substrate main body 6 in step S3 described below. For example, silicon can be used as the material forming the hard mask 90, in addition to the tungsten silicide described above.

The hard mask 90 is an example of “mask” in the present invention.

FIG. 8(a) illustrates the state after passing through step S1. As illustrated in FIG. 8(a), the hard mask 90 is formed by covering the front surface 6a of the substrate main body 6.

In step S2 of FIG. 7, an opening 92 for exposing the front surface 6a of the substrate main body 6 is formed by a known technique, for example, by performing anisotropic etching using a mixed gas of chlorine and oxygen on the hard mask 90, with a resist (not illustrated) formed by a photolithographic method as a mask.

FIG. 8(b) illustrates the state after passing through step S2. The wall surface 91 of the opening 92 is formed along the Z direction. The front surface 6a of the substrate main body 6 is exposed through the opening 92 surrounded by the wall surfaces 91 along the Z direction. The dimension W1 in the Y direction of the opening 92 is approximately 1000 nm to 2000 nm, and the substrate main body 6 exposed through the opening 92 is etched in the subsequent step (step S3). Hereinafter, the dimension in the Y direction of a region of the substrate main body 6 exposed through the opening 92 is referred to as an opening dimension. In FIG. 8(b), the opening dimension is W1.

Next, with the hard mask 90 as an etching mask, anisotropic etching is performed on the hard mask 90 and the substrate main body 6. In order to clarify the effects of the step of performing anisotropic etching on the hard mask 90 and the substrate main body 6, the step of performing anisotropic etching on the hard mask 90 and the substrate main body 6 will be divided into step S3 and step S4 and described below.

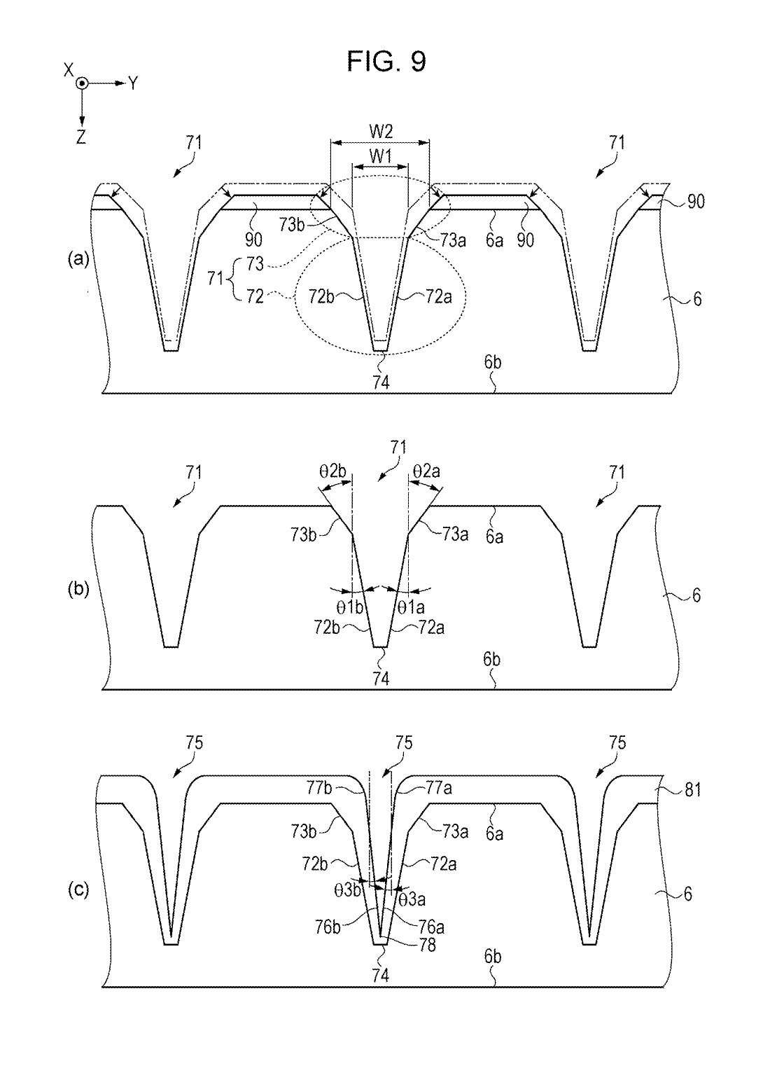

If the hard mask 90 is etched, the dimension in the Y direction as well as the dimension in the Z direction (film thickness) in the hard mask 90 change. As a result, as illustrated in FIG. 8(c) and FIG. 9(a), the position of the wall surface 91 of the hard mask 90 changes (retracts) in the direction indicated by arrows in FIG. 8(c) and FIG. 9(a), in other words, a direction that intersects the Z direction. If the reaction amount of the wall surface 91 of the hard mask 90 is increased, the dimension (opening dimension) of a region of the front surface 6a of the substrate main body 6 changes. Step S3 illustrated in FIG. 7 corresponds to a state where the reaction amount of the wall surface 91 of the hard mask 90 is small and the opening dimension does not change. Step S4 corresponds to a state where the reaction amount of the wall surface 91 of the hard mask 90 is great and the opening dimension changes. Further, in step S3 and step S4, etching is continuously performed under the same conditions.

Step S3 and step S4 are an example of the “step of performing anisotropic etching on the substrate that is exposed through the opening while etching a mask in order for the wall surface to retract” in the present invention.

In step S3 of FIG. 7, anisotropic etching is performed on the hard mask 90 and the substrate main body 6 exposed through the opening 92 by using a known technique, for example, ICP-RIE/Inductive Coupled Plasma-RIE (ICP) capable of forming high density plasma, and a precursor groove 68 is formed on the front surface 6a of the substrate main body 6. If for example, a mixed gas of fluorine-based gas and oxygen is used as an etching gas, the ratio of the etching rate of the hard mask 90 (tungsten silicide) and the etching rate of the substrate main body 6 (quartz) can be 1:10 or more.

In addition, the precursor groove 68 is a first groove 71 in step S4 to be described later.

FIG. 8(c) illustrates the state after passing through step S3. Further, two-dot chain lines in FIG. 8(c) represent the outline (FIG. 8(b)) of the hard mask 90 after passing through step S2, and the solid lines in FIG. 8(c) represent the retracting direction of the wall surface 91.

With respect to the hard mask 90, the end portion (top of the wall surface 91) of the hard mask 90 is more easily etched as compared to the surface along the Y direction of the hard mask 90, and the wall surface 91 retracts in a direction that intersects the Z direction (the direction indicated by arrows). If the position of the wall surface 91 retracts in the arrow direction, the wall surface 91 changes from the state of being vertical to the Y direction to the state of being inclined with respect to the Y direction. The opening dimension W1 in step S3 maintains the same dimension as in step S2 (approximately 1000 nm to 2000 nm).

In step S3, the substrate main body 6 in the exposed region of the opening dimension W1 (approximately 1000 nm to 2000 nm) is etched in the Z direction (depth direction) while a protective film (for example, CF polymer) generated in an etching process is accumulated in the side wall. In other words, the substrate main body 6 is etched in the Z direction (depth direction) while suppressing the etching in the Y direction (lateral direction) with protective material. The side wall of the precursor groove 68 is processed into a so-called tapered shape so as to be inclined to intersect with the Z direction. In step S3, the precursor groove 68 of a depth (the length in the Z direction) of 25000 nm is formed.

In order to continuously perform etching in the Z direction (depth direction), a region where an etching reaction occurs (etched region) is required, as illustrated in a region surrounded by broken line D, an etched region (bottom surface 74) widening in the Y direction is formed at the bottom of the precursor groove 68. If the region surrounded by a broken line is V-shaped, in other words, a shape in which the side walls are connected with each other, the etching of the side walls is suppressed by the protective film, such that the etching in the Z direction as well as the Y direction is suppressed and it is difficult to perform deep etching in the Z direction.

Further, in order to continuously perform etching in the Z direction (depth direction), it is necessary to discharge the reaction product generated by the etching reaction from the etched region in addition to the above description. For example, if the reaction product is retained in the etched region, the etching reaction is suppressed and the etching in the Z direction is less likely to progress.

In step S4 of FIG. 7, the first groove 71 is formed on the front surface 6a of the substrate main body 6 by performing anisotropic etching on the hard mask 90 and the substrate main body 6 exposed through the opening 92 under the same conditions as in step S3.

FIG. 9(a) illustrates the state after passing through step S4. Further, two-dot chain lines in FIG. 9(a) represent the outline (FIG. 8(c)) of the hard mask 90 after passing through step S3, and the solid lines in FIG. 9(a) represent the retracting direction of the wall surface 91.

In step S4, while the dimension (opening dimension) in the Y direction of the region in which the substrate main body 6 is exposed changes, in other words, the opening dimension W2 is increased, the substrate main body 6 is etched in the depth direction.

Here, an angle that the Y direction makes with the side wall is defined as a taper angle. A region of the taper angle being reduced (a region of a low gradient) is formed on the front surface 6a side of the substrate main body 6 by etching the substrate main body 6 in the depth direction while increasing the opening dimension W2 of the opening 92. As a result, two types of regions having different taper angles are formed in the first groove 71. The first groove 71 of the region of the taper angle being reduced (a region of a low gradient) corresponds to a lower groove 73. The first groove 71 of a region of the taper angle being increased (a region of a high gradient) corresponds to an upper groove 72. The side walls of the first groove 71 of the region of the taper angle being reduced correspond to second slopes 73a and 73b. The side walls of the first groove 71 of the region of the taper angle being increased correspond to first slopes 72a and 72b.

In step S4, a widely opening region having a small tapered angle is formed on the front surface 6a side of the substrate main body 6. The widely opening region corresponds to supply and exhaust ports for the reaction gas used in the dry etching. Since the supply and exhaust ports for the reaction gas are widened, it is possible to smoothly exhaust (discharge) the above-mentioned reaction product from the etched region or smoothly supply (feed) etching gas to the etched region. In other words, it is possible to cause the etching in the Z direction (depth direction) to proceed smoothly, by providing the widely opening region on the front surface 6a side of the substrate main body 6. As a result, it is possible to form the first groove 71 which is deeper and has a higher gradient.

In step S4, the first groove 71 is formed in which the opening dimension (the length in the Y direction) in the front surface 6a of the substrate main body 6 is 1500 nm to 2500 nm, and the depth (the length in the Z direction) is approximately 30000 nm. Further, the region widening in the Y direction (bottom surface 74) is formed in the bottom of the first groove 71.

In step S5 of FIG. 7, the hard mask 90 is selectively removed by a known technique, for example, dry etching using a mixed gas of chlorine and oxygen.

FIG. 9(b) illustrates the state after passing through step S5. As illustrated in FIG. 9(b), the first groove 71 of a shape widening in a direction from the back surface 6b side of the substrate main body 6 towards the front surface 6a side of the substrate main body 6, in other words, the Z(−) direction is formed. The first groove 71 includes a region (lower groove 73) having slopes (second slopes 73a and 73b) of a low gradient which are arranged on the front surface 6a side of the substrate main body 6, and a region (upper groove 72) having slopes (first slopes 72a and 72b) of a high gradient which are arranged on the back surface 6b side of the substrate main body 6. The tilt angles θ2a and θ2b of the second slopes 73a and 73b are greater than the tilt angles θ1a and θ1b of the first slopes 72a and 72b, the tilt angles θ2a and θ2b of the second slopes 73a and 73b are in the range of 4 degrees to 7 degrees, and the tilt angles θ1a and θ1b of the first slopes 72a and 72b are in the range of 1 degree to 3 degrees.

In step S6 of FIG. 7, the first insulating film 81 is formed by accumulating a silicon oxide by a film formation method excellent in step coverage, for example, plasma CVD using tetraethoxysilane (TEOS: Si(OC₂H₅)₄). The first insulating film 81 covers the first groove 71, and a second groove 75 is formed at a position corresponding to the first groove 71.

FIG. 9(c) illustrates the state after passing through step S6. The plasma CVD is a film forming method for forming a silicon oxide by decomposing a metal gas such as silane (SiH₄) and TEOS and an oxidizing gas such as nitrous oxide (N₂O) and oxygen (a material gas as an oxygen supply source) in the plasma, and causing a precursor radical of a reaction product generated from the material gas to react with an oxygen radical generated from the oxidizing gas. Further, in the plasma CVD, a silicon oxide is accumulated through processes of a vapor-phase reaction process, a front surface reaction process, and a deposited film reaction process. In the plasma CVD using TEOS, the front surface reaction process is dominant, the precursor radical that is formed in the plasma is attracted to the front surface of the first groove 71 and reacts with the oxygen radical so as to form a silicon oxide. Since the precursor radical is likely to enter the inside of the first groove 71, a silicon oxide that is formed by the plasma CVD using TEOS is excellent in step coverage, and is capable of easily covering the entire region (the first slopes 72a and 72b, the second slopes 73a and 73b, and the bottom surface 74) in the inside of the first groove 71.

Further, the first groove 71 has a widely opening region having a small tapered angle on the front surface 6a side of the substrate main body 6. The widely opening region corresponds to the inlet of the precursor radical. Since the inlet of the precursor radical is wide, the precursor radical is likely to enter the inside of the first groove 71, and a silicon oxide that is formed by the plasma CVD using TEOS is capable of easily covering the entire region of the first groove 71. As a result, the front surface of the first groove 71 (the first slopes 72a and 72b, the second slopes 73a and 73, and the bottom surface 74) is covered with the first insulating film 81, and the second groove 75 is formed at a position corresponding to the first groove 71.

In a vacuum deposition method such as plasma CVD and sputtering, as compared to a flat region where the first groove 71 is not formed, a film raw material (the precursor radical) is less likely to be supplied to a recessed region where the first groove 71 is formed. For this reason, the formation rate of the first insulating film 81 (the film forming rate of a silicon oxide) is reduced from the top side of the first groove 71 to the bottom side of the first groove 71. In other words, the film thickness of the first insulating film 81 is reduced from the top side of the first groove 71 to the bottom side of the first groove 71. As a result, as illustrated in FIG. 9(c), the film thickness of the first insulating film 81 that covers the slopes (first slopes 72a and 72b, and the second slopes 73a and 73b) of the first groove 71 is reduced from the front surface 6a side of the substrate main body 6 to the back surface 6b side thereof.

Since the front surfaces of the first insulating film 81 that covers the first slopes 72a and 72b of the first groove 71 are third slopes 76a and 76b of the second groove 75, and the film thickness of the first insulating film 81 is reduced from the front surface 6a side of the substrate main body 6 to the back surface 6b side thereof, the slopes of third slopes 76a and 76b which are provided on the inner side of the first slopes 72a and 72b are steeper than the first slopes 72a and 72b. In this manner, the second groove 75 having the slope of the higher gradient is formed by covering the slope of the first groove 71 with the first insulating film 81. Specifically, the third slopes 76a and 76b with the tilt angles θ3a and θ3b which are smaller by 3 degrees than the tilt angles θ1a and θ1b of the first slopes 72a and 72b are formed.

Further, in the case of using a vacuum deposition method such as plasma CVD and sputtering, a film raw material (the precursor radical) is likely to be supplied to a surface (bottom surface 74) in the Z direction of the first groove 71, as compared to the surface (the first slopes 72a and 72b, and the second slopes 73a and 73) in the Y direction of the first groove 71; and the first insulating film 81 is likely to be deposited on a surface in the Z direction of the first groove 71, as compared to the surface in the Y direction of the first groove 71. In this manner, in the vacuum deposition method such as plasma CVD and sputtering, there is anisotropy in which accumulating a film on the surface in the Y direction is difficult and accumulating a film on the surface in the Z direction is easy. Through the anisotropy, the shape of the bottom surface 74 that is widened in the Y direction in the bottom of the first groove 71 is alleviated, and this is less likely to affect the shape of the bottom of the second groove 75. As a result, the second groove 75 has a sharp shape in a direction from the top side (the front surface 6a side of the substrate main body 6) towards the bottom side (the back surface 6b side of the substrate main body 6), and the region widening in the Y direction occurring on the bottom side of the first groove 71 is eliminated.

Further, the second groove 75 has a steeper (high gradient) shape in a direction from the front surface 6a side of the substrate main body 6 towards the back surface 6b side of the substrate main body 6 by the anisotropy. As a result, the tilt angles θ3a and θ3b of the third slopes 76a and 76b of the second groove 75 are small in a direction from the front surface 6a side of the substrate main body 6 towards the back surface 6b side of the substrate main body 6.

A steeper pointed shape in a direction from the front surface 6a side of the substrate main body 6 towards the back surface 6b side of the substrate main body 6 is more preferable as the reflection surface of the prism 70. In other words, it is possible to form the prism 70 of a more preferable shape by a manufacturing method according to the present embodiment.

In step S7 of FIG. 7, a second insulating film 82 is formed by accumulating a silicon oxide by a film forming method with poor step coverage, for example, plasma CVD using silane. The second insulating film 82 blocks the opening of the second groove 75, and the air layer 85 is formed in a region (blocked region) surrounded by the second insulating film 82 and the second groove 75. Then, a prism 70 which is configured with the first groove 71, the first insulating film 81, the second groove 75, the second insulating film 82, and the air layer 85 is formed.

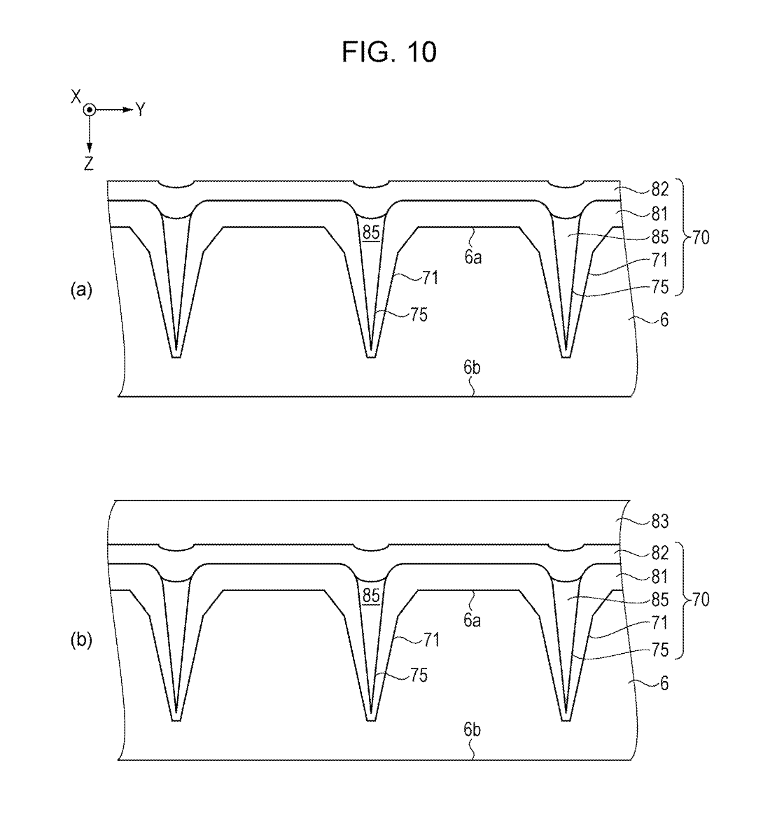

FIG. 10(a) illustrates the state after passing through step S7. Since the Plasma CVD using silane has high reactivity of the silane, vapor-phase reaction process (chemical reaction in the vapor-phase) is dominant. In other words, the precursor radical reacts with the oxygen radical primarily in the vapor-phase, and a silicon oxide produced in the vapor-phase is accumulated on the front surface of the first insulating film 81. A silicon oxide, which is generated in the vapor-phase, is less likely to enter the second groove 75, is thickly formed on the top side of the second groove 75, and closes (seals) the opening portion of the top of the second groove 75. In this case, the second groove 75 is sealed in a state of an atmosphere at the time of accumulating a silicon oxide. Specifically, the gas used at the time of accumulating the silicon oxide by plasma CVD using silane is sealed in a region surrounded by the second insulating film 82 and the second groove 75 in a reduced pressure state, and thus the air layer 85 is formed.

In step S8 of FIG. 7, a third insulating film 83 having a flat surface is formed by performing a flattening process after accumulating a silicon oxide by, for example, the plasma CVD using TEOS.

FIG. 10(b) illustrates the state after passing through step S8. A third insulating film 83 that covers the second insulating film 82 is formed by performing a flattening process on a silicon oxide formed by a film forming method excellent in step coverage, for example, plasma CVD using TEOS, by for example, Chemical Mechanical Polishing, (hereinafter, referred to as CMP). It is possible to obtain a flat polished surface at a high speed in CMP, by the balance with a chemical action of chemical components contained in a polishing liquid and a mechanical action due to relative movement between the abrasive and the element substrate 10. As a result, surface irregularities caused by forming the prism 70 are eliminated, and a third insulating film 83 with a flat surface is formed.

In addition, when it is difficult to block the opening portion of the top portion of the second groove 75 simply by accumulating the second insulating film 82 described above, polysilicon that is a sacrificial film is buried and deposited in the inside of the second groove 75, and buried and flattened by a damascene method. The second insulating film 82 is accumulated on the upper layer. Further, the inside of the second groove 75 is in the form of a cavity by forming a small hole for etching in the second insulating film 82, and selectively removing the etched sacrificial film. Thereafter, it is possible to form a prism 110 in which an air layer 85 is sealed in the inside of the second groove 75, by accumulating a third insulating film 83 and closing the small hole for etching. In this case, the air layer 85 is formed by sealing gas used when accumulating a silicon oxide (third insulating film 83) by plasma CVD using TEOS in a region surrounded by the second insulating film 82 and the second groove 75 in a pressed state.

### Embodiment 2

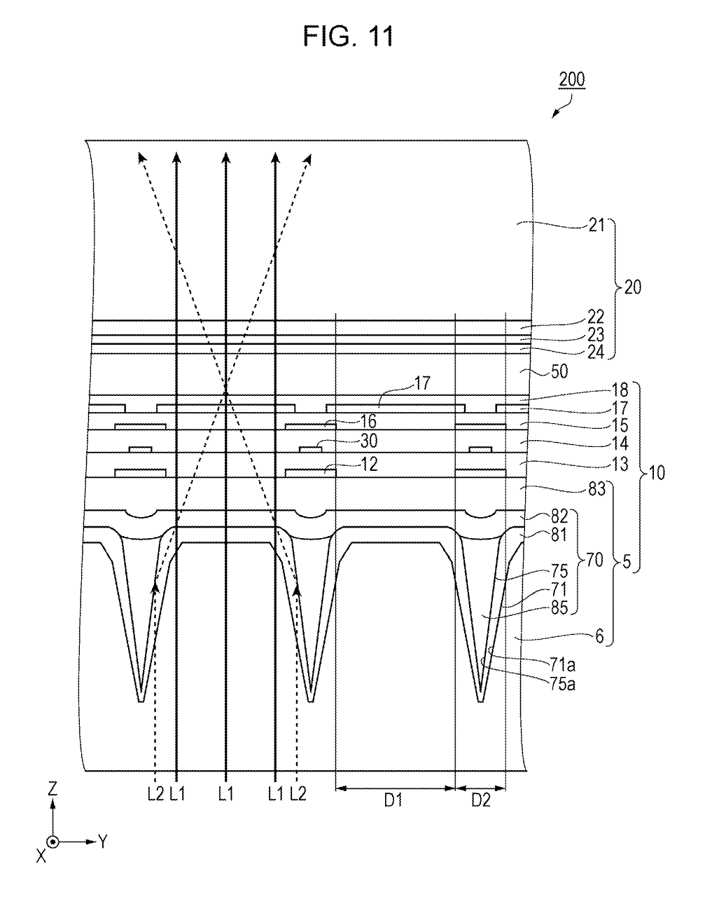

FIG. 11 is a schematic cross-sectional view of a liquid crystal device according to Embodiment 2, and corresponds to FIG. 5.

Hereinafter, with reference to FIG. 11, a liquid crystal device 200 according to the present embodiment will be described focusing on the difference from Embodiment 1. Further, the same components as in Embodiment 1 are denoted by the same reference numerals, and a redundant description thereof will be omitted.

In the liquid crystal device 100 according to Embodiment 1, the substrate 5 for an electro-optical device is used for the counter substrate 20. In the liquid crystal device 200 according to the present embodiment, the substrate 5 for an electro-optical device is used for the element substrate 10. This is the difference between the present embodiment and Embodiment 1, and the rest of the configuration is the same as in Embodiment 1.

As illustrated in FIG. 11, the counter substrate 20 includes a counter substrate main body 21, and a light shielding film 53 (not illustrated), an insulating film 22, a counter electrode 23, an alignment film 24, and the like, which are stacked in this order on the surface of the liquid crystal layer 50 side of the counter substrate main body 21. For example, a quartz substrate is used for the counter substrate main body 21.

The element substrate 10 includes a substrate 5 for an electro-optical device, and a scan line 12, an insulating layer 13, a TFT 30, an insulating layer 14, a data line 16, an insulating layer 15, a pixel electrode 17, an alignment film 18 and the like, which are stacked in order on the surface of the liquid crystal layer 50 side of the substrate 5 for an electro-optical device.

On the substrate 5 for an electro-optical device, the prism 70 which is a light reflection portion is provided in the non-opening region D2. The slope 75a of the second groove 75 forming the light reflection surface of the prism 70 is arranged while widening in a direction from the back surface 6b side of the substrate main body 6 towards the front surface 6a side of the substrate main body 6, in other words, the Z direction.

The liquid crystal device 200 according to the present embodiment is an optical modulation element (light valve) that can be suitably used for a liquid crystal projector which will be described later, and light emitted from the light source is incident on the counter substrate 20 side from the element substrate 10 side. The light incident on the liquid crystal device 200 becomes display light of the liquid crystal projector by being modulated in the opening region D1, and emitted in the Z direction.

The incident light L1 traveling to the opening region D1 passes through the opening region D1, emitted in the Z direction and becomes display light. The incident light L2 traveling to the non-opening region D2 is reflected on the prism 70 (the slope 75a of the second groove 75), passes through the opening region D1, is emitted in the Z direction and becomes display light. In this manner, since it is possible to use the incident light L2 traveling to the non-opening region D2 in addition to the incident light L1 traveling to the opening region D1 as the display light by the prism 70, it is possible to improve the utilization efficiency of the incident light as compared to the case of not forming the prism 70, and thus a bright display is realized.

In addition, even when light emitted from the light source enters from the counter substrate 20 side to the element substrate 10 side, it is possible to improve the utilization efficiency of the incident light by the prism 70.

### Embodiment 3

“Electronic Equipment”

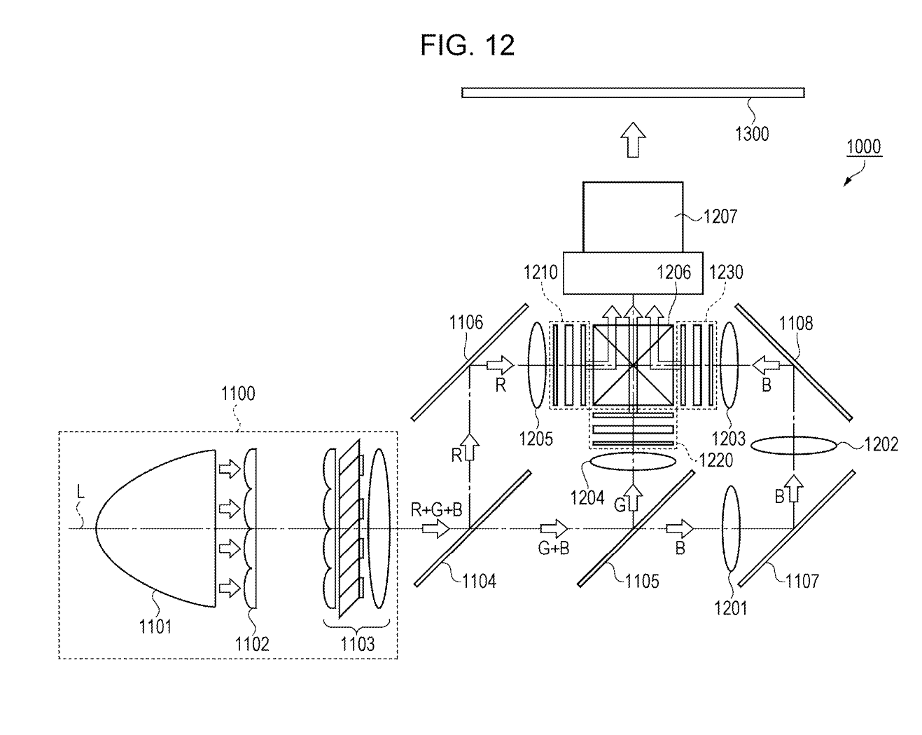

FIG. 12 is a schematic diagram illustrating the configuration of a projection type display apparatus (liquid crystal projector) as electronic equipment. As illustrated in FIG. 12, a projection type display apparatus 1000 which is the electronic equipment of the present embodiment includes a polarizing illumination device 1100 arranged along a system optical axis L, two dichroic mirrors 1104 and 1105 which are light splitting elements, three reflecting mirrors 1106, 1107, and 1108, five relay lenses 1201, 1202, 1203, 1204, and 1205, three transmission type liquid crystal light valves 1210, 1220, and 1230 which are light modulation means, a cross dichroic prism 1206 which is a photosynthesis element, and a projection lens 1207.

The polarizing illumination device 1100 is roughly configured with a lamp unit 1101 which is a light source having a white source such as an ultrahigh pressure mercury lamp or a halogen lamp, an integrator lens 1102, and a polarization conversion element 1103.

The dichroic mirror 1104 reflects red light (R), and transmits green light (G) and blue light (B), among polarized light beams emitted from the polarizing illumination device 1100. Another dichroic mirror 1105 reflects the green light (G) that has passed through the dichroic mirror 1104, and passes the blue light (B).

The red light (R) that has been reflected on the dichroic mirror 1104 is reflected on the reflecting mirror 1106, and enters the liquid crystal light valve 1210 through the relay lens 1205.

The green light (G) that has been reflected on the dichroic mirror 1105 enters the liquid crystal light valve 1220 through the relay lens 1204.

The blue light (B) that has passed through the dichroic mirror 1105 enters the liquid crystal light valve 1230 through a light guide system configured with three relay lenses 1201, 1202, and 1203 and two reflecting mirrors 1107 and 1108.

The liquid crystal light valves 1210, 1220, and 1230 are respectively arranged facing an incident plane of each color light of the cross dichroic prism 1206. The color light that enters the liquid crystal light valves 1210, 1220, and 1230 is modulated based on image information (image signal), and emitted to the cross dichroic prism 1206. In the prism, four right-angle prisms are bonded, and a dielectric multilayer film reflecting the red light and a dielectric multilayer film reflecting the blue light are formed in a cross shape in the inside of the prism. Three beams of color light are synthesized by the dielectric multilayer films, and light beams representing a color image are synthesized. The synthesized light is projected on a screen 1300 by a projection lens 1207 which is a projection optical system, and an image is enlarged and displayed.

The liquid crystal device 100 of Embodiment 1 and the liquid crystal device 200 of Embodiment 2, which are described above, are applied to the liquid crystal light valves 1210, 1220, and 1230. It is possible to enhance the utilization efficiency of the light by the substrate 5 for an electro-optical device (prism 70) used for the liquid crystal device 100 and the liquid crystal device 200, and realize a brighter display.

The present invention is not limited to the Embodiments described above, and can be approximately changed in a scope without departing from the essence or spirit of the invention read from the claims and the entire specification, and a liquid crystal device and electronic equipment employing the liquid crystal device, which are involved with this change, are intended to be within the technical scope of the present invention.

Various modification examples are considered in addition to the above embodiments. Hereinafter, modification examples will be described.

### MODIFICATION EXAMPLE 1

The substrate for an electro-optical device is not limited to being applied to the liquid crystal devices 100 and 200, and may also be applied to, for example, a light emitting device having an organic electroluminescent element. Since it is possible to enhance the utilization efficiency of the light by the substrate 5 for an electro-optical device (prism 70), it is possible to realize a brighter display in the light emitting device having the substrate 5 for an electro-optical device (prism 70).

### MODIFICATION EXAMPLE 2

The substrate 5 for an electro-optical device may be used for both the element substrate 10 and the counter substrate 20. In other words, the substrate 5 for an electro-optical device may be used for at least one of the element substrate 10 and the counter substrate 20.

### MODIFICATION EXAMPLE 3

The electronic equipment to which the liquid crystal device 100 or 200 is applied is not limited to a projection-type display apparatus 1000 of Embodiment 3. It is possible to apply the liquid crystal device 100 or 200 to an information terminal device such as a projection-type head-up display (HUD), a direct-view-type head mounted display (HMD), or an e-book, a personal computer, a digital still camera, an LCD TV, a viewfinder type or monitor direct-view-type video recorder, a car navigation system, and a POS, and electronic equipment such as an electronic organizer, in addition to the projection-type display apparatus 1000.

### REFERENCE SIGNS LIST

5 A SUBSTRATE FOR AN ELECTRO-OPTICAL DEVICE

6 SUBSTRATE MAIN BODY

6a FRONT SURFACE

6b BACK SURFACE

10 ELEMENT SUBSTRATE

11 ELEMENT SUBSTRATE MAIN BODY

12 SCAN LINE

13, 14, 15 INSULATING LAYER

16 DATA LINE

17 PIXEL ELECTRODE

18 ALIGNMENT FILM

20 COUNTER SUBSTRATE

21 COUNTER SUBSTRATE MAIN BODY

22 INSULATING FILM

23 COUNTER ELECTRODE

24 ALIGNMENT FILM

30 TFT

40 STORAGE CAPACITOR

41 CAPACITY LINE

50 LIQUID CRYSTAL LAYER

52 SEALING MEMBER

53 LIGHT SHIELDING FILM

68 PRECURSOR GROOVE

70 PRISM

71 FIRST GROOVE

71a SLOPE

72 UPPER GROOVE

72a FIRST SLOPE

72b FIRST SLOPE

73 LOWER GROOVE

73a SECOND SLOPE

73b SECOND SLOPE

74 BOTTOM SURFACE

75 SECOND GROOVE

75a SLOPE

76 UPPER GROOVE

76a THIRD SLOPE

76b THIRD SLOPE

77 LOWER GROOVE

77a FOURTH SLOPE

77b FOURTH SLOPE

78 BOTTOM SIDE

81 FIRST INSULATING FILM

82 SECOND INSULATING FILM

83 THIRD INSULATING FILM

85 AIR LAYER

90 HARD MASK

91 WALL SURFACE

92 OPENING

100, 200 LIQUID CRYSTAL DEVICE

101 DATA LINE DRIVING CIRCUIT

102 EXTERNAL CONNECTION TERMINAL

104 SCANNING LINE DRIVING CIRCUIT

105 WIRING

106 VERTICAL CONDUCTION PORTION

This application claims priority to Japan Patent Application No. 2013-42665 filed Mar. 5, 2013, the entire disclosures of which are hereby incorporated by reference in their entireties.

1. A substrate for an electro-optical device, comprising:
a substrate that includes a first surface, a second surface facing the first surface, and first slopes and second slopes being arranged from the first surface towards the second surface, and transmits light;
a first insulating film that covers the first slopes and the second slopes;
a groove that includes third slopes being surfaces of the first insulating film covering the first slopes, and fourth slopes being surfaces of the first insulating film covering the second slopes, and widens in a direction from the second surface towards the first surface; and
a second insulating film that covers the groove and the first insulating film,
wherein a part of the second insulating film that covers the groove has a set distance with the third slopes,
the second slopes rather than the first slopes are arranged on the first surface side, and
each of angles that the second slopes make with a normal line of the first surface is greater than each of angles that the first slopes make with the normal line.

2. The substrate for an electro-optical device according to claim 1,
wherein each of angles that the first slopes make with the normal line is in the range of 1 degree to 3 degrees, and each of angles that the second slopes make with the normal line is in the range of 4 degrees to 7 degrees.

3. The substrate for an electro-optical device according to claim 2,
wherein each of angles that the third slopes make with the normal line is smaller than 3 degrees.

4. The substrate for an electro-optical device according to claim 3,
wherein the third slopes include slopes which are arranged so as to be plane-symmetric with respect to a plane orthogonal to the first surface, and
wherein the slopes that are arranged so as to be plane-symmetric are connected in a direction from the first surface to the second surface.

5. The substrate for an electro-optical device according to claim 1,
wherein the first insulating film is a silicon oxide that is formed by plasma CVD using tetraethoxysilane gas.

6. The substrate for an electro-optical device according to claim 1,
wherein the substrate, the first insulating film, and the second insulating film have approximately the same refractive index, and
the refractive index of a region surrounded by the groove and the second insulating film is smaller than the refractive index of the substrate.

7. An electro-optical device comprising:
a first substrate including pixel electrodes, and transistors that drive the pixel electrodes; and
a second substrate that is arranged so as to face the first substrate,
wherein at least one of the first substrate and the second substrate includes the substrate for an electro-optical device according to claim 1.

8. Electronic equipment comprising the electro-optical device according to claim 7.

9. A manufacturing method for the substrate for an electro-optical device according to claim 1, comprising:
accumulating a mask on the first surface of the substrate;
forming an opening surrounded by a wall surface in which the substrate is exposed, by performing anisotropy etching on the mask;
performing anisotropy etching on the substrate which is exposed in the opening, while etching the mask so that the wall surface retracts;
removing the mask; and
forming a groove by accumulating a silicon oxide by plasma CVD using tetraethoxysilane gas.

10. The method for manufacturing a substrate for an electro-optical device according to claim 9,
wherein a forming material of the substrate is quartz, and
a forming material of the mask is either a tungsten silicide or silicon.

11. A method for manufacturing an electro-optical device, comprising:
accumulating a mask on a first surface of a substrate;
forming an opening on the mask;
forming a first groove having first slopes and second slopes by performing anisotropy etching on the substrate from the opening side;
removing the mask;
forming a first insulating film that covers the first slopes and the second slopes; and
forming a second insulating film that covers the first groove and the first insulating film,
wherein the second slopes rather than the first slopes are arranged on the first surface side,
a part of the second insulating film that covers the groove has a set distance with the third slopes being surfaces of the first insulating film which covers the first slopes, and
each of angles that the second slopes make with a normal line of the first surface is greater than each of angles that the first slopes make with the normal line.
